(19) United States
(12) Patent Application Publication
(10) Pub. No.: US 2026/0191091 A1
(43) Pub. Date: Jul. 2, 2026

(54) SEMICONDUCTOR DEVICE

(71) Applicant: Mitsubishi Electric Corporation, Tokyo (JP)

(72) Inventor: Hiroshige SUGIMOTO, Tokyo (JP)

(73) Assignee: Mitsubishi Electric Corporation, Tokyo (JP)

(21) Appl. No.: 19/130,932

(22) PCT Filed: Jan. 13, 2023
(86) PCT No.: PCT/JP2023/000733

§ 371 Date: May 16, 2025

(51) Int. Cl. H10W 76/18

(52) U.S. Cl. CPC H10W 76/18

(57) ABSTRACT

A semiconductor device includes a semiconductor element, an insulating substrate to which the semiconductor element is mounted; a metal base plate to which the insulating substrate is mounted; and a resin case provided on the metal base plate to surround the insulating substrate. The metal base plate includes a plurality of first fastening holes, and the resin case includes a plurality of second fastening holes disposed to be overlapped with the plurality of first fastening holes. A protrusion restricting pivot of the resin case is provided in a region between the first fastening holes adjacent to each other in the metal base plate.

### TECHNICAL FIELD

The present disclosure relates to a semiconductor device, and particularly to a semiconductor device having a package structure including a metal base plate and a resin case.

### BACKGROUND ART

For example, Patent Document 1 discloses a semiconductor device having a package structure including a metal base plate for heat radiation and a resin case. In Patent Document 1, the resin case has pressure-contact with the metal base plate to which an adhesive agent is applied and is heated to cure the adhesive agent, thereby bonding the metal base plate and the resin case.

### PRIOR ART DOCUMENTS

### Patent Document(s)

Patent Document 1: Japanese Patent Application Laid-Open No. 8-31967

### SUMMARY

### Problem to be Solved by the Invention

In a process of bonding the metal base plate and the resin case, there is a method of fastening the metal base plate and the resin case with a screw together with a jig on which the resin case is disposed as a method of pressure-contacting the metal base plate and the resin case. When this method is applied, the metal base plate and the resin case are heated while being fastened with the screw and the adhesive agent is cured, and subsequently, the screw fastening the metal base plate and the resin case are detached.

However, in this method, a position of the resin case may be displaced with respect to the metal base plate with a first fastening position as a center due to a torque in fastening a screw at the first fastening position. When the adhesive agent is cured in a state where the resin case is displaced with respect to the metal base plate, positional displacement occurs between a fastening hole of the resin case and a fastening hole of the metal base plate in a semiconductor device as a completed product. When the positional displacement of the fastening hole occurs, the screw interferes with an inner wall of the fastening hole of the metal base plate in fixing the semiconductor device to a cooling fin, and this interference leads to defect in attaching the cooling fin.

The present disclosure therefore has been made to solve the above problems, and it is an object to provide a semiconductor device capable of preventing positional displacement between a fastening hole of a resin case and a fastening hole of a metal base plate.

### Means to Solve the Problem

A semiconductor device according to the present disclosure includes: a semiconductor element; an insulating substrate to which the semiconductor element is mounted; a metal base plate to which the insulating substrate is mounted; a resin case provided on the metal base plate to surround the insulating substrate; a plurality of first fastening holes formed in the metal base plate; a plurality of second fastening holes formed in the resin case and disposed to be overlapped with the plurality of first fastening holes; and at least one protrusion provided in a region between the first fastening holes adjacent to each other in the metal base plate to restrict pivot of the resin case.

### Effects of the Invention

According to the semiconductor device in the present disclosure, the protrusion restricting the pivot of the resin case is provided to the metal base plate; thus, the positional displacement between the first fastening hole of the resin case and the second fastening hole of the metal base plate can be prevented.

These and other objects, features, aspects and advantages of the present disclosure will become more apparent from the following detailed description of the present disclosure when taken in conjunction with the accompanying diagrams.

### BRIEF DESCRIPTION OF DRAWINGS

FIG. 1 is a plan view illustrating a configuration of a semiconductor device according to an embodiment 1.

FIG. 2 is a plan view that a resin case of the semiconductor device according to the embodiment 1 is omitted.

FIG. 3 is a cross-sectional view along an A1-A2 line in FIG. 1.

FIG. 4 is a plan view illustrating a configuration of a semiconductor device according to an embodiment 2.

FIG. 5 is a plan view that a resin case of the semiconductor device according to the embodiment 2 is omitted.

FIG. 6 is a plan view illustrating a configuration of a semiconductor device according to an embodiment 3.

FIG. 7 is an enlarged view of a region R in FIG. 6.

FIG. 8 is a plan view illustrating a configuration of a semiconductor device according to an embodiment 4.

FIG. 9 is a plan view that a resin case of the semiconductor device according to the embodiment 4 is omitted.

FIG. 10 is a plan view illustrating a configuration of a semiconductor device according to an embodiment 5.

FIG. 11 is a plan view that a resin case of the semiconductor device according to the embodiment 5 is omitted.

FIG. 12 is a cross-sectional view along an A1-A2 line in FIG. 10.

FIG. 13 is a plan view illustrating a configuration of a semiconductor device according to an embodiment 6.

FIG. 14 is a plan view that a resin case of the semiconductor device according to the embodiment 6 is omitted.

FIG. 15 is a cross-sectional view along an A1-A2 line in FIG. 13.

FIG. 16 is a plan view illustrating a configuration of a semiconductor device according to an embodiment 7.

FIG. 17 is a plan view that a resin case of the semiconductor device according to the embodiment 7 is omitted.

FIG. 18 is a cross-sectional view along an A1-A2 line in FIG. 16.

### DESCRIPTION OF EMBODIMENT(S)

### Embodiment 1

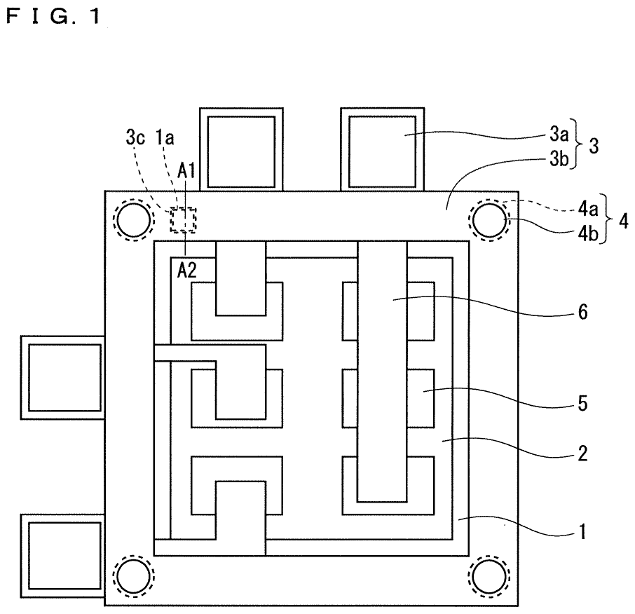

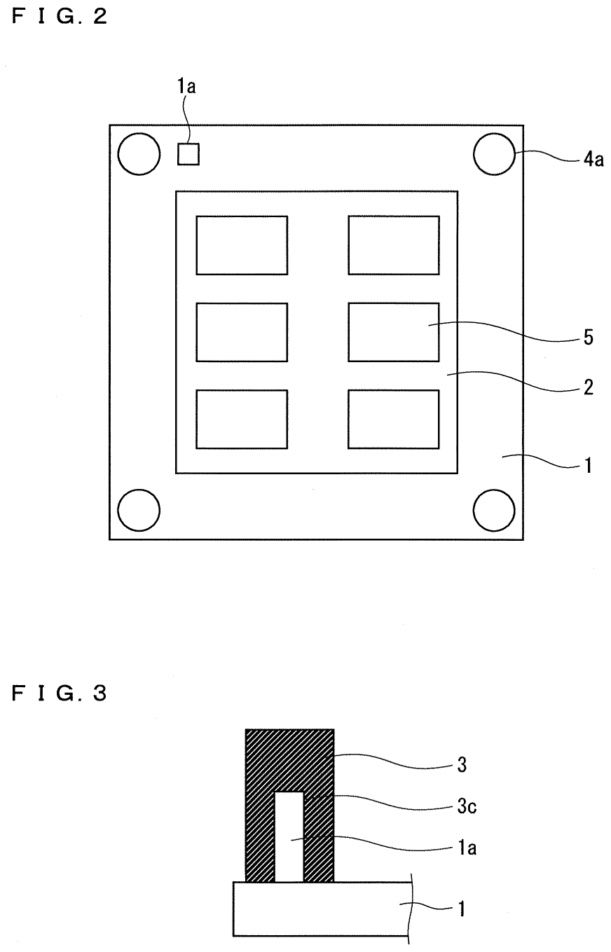

FIG. 1, FIG. 2, and FIG. 3 are diagrams each illustrating a configuration of a semiconductor device according to an embodiment 1. FIG. 1 is a plan view of the semiconductor device, FIG. 2 is a plan view that a resin case of the semiconductor device is omitted from FIG. 1, and FIG. 3 is cross-sectional view along an A1-A2 line in FIG. 1.

As illustrated in FIG. 1, the semiconductor device according to the embodiment 1 includes a semiconductor element 5, an insulating substrate 2 to which the semiconductor element 5 is mounted, a metal base plate 1 to which the insulating substrate 2 is mounted, and a resin case 3 provided on the metal base plate 1 to surround the insulating substrate 2.

The metal base plate 1 is formed by a material such as aluminum alloy or copper, for example, excellent in heat conductivity. Although illustration is omitted, the insulating substrate 2 is made up of an insulating layer and a circuit pattern bonded to both surfaces of the insulating layer. The insulating layer is made up of ceramic or resin such as aluminum nitride or silicon nitride excellent in heat conductivity, for example, the circuit pattern is formed by a conductive material such as aluminum alloy or copper excellent in heat conductivity, and the insulating layer and the circuit pattern are bonded by a bonding material such as a solder or a soft solder. The semiconductor element 5 is bonded to a circuit pattern on the insulating substrate 2 using a bonding material. Herein, the plurality of semiconductor elements 5 are mounted on a metal lead electrode 6, and the plurality of semiconductor elements 5 are connected via the metal lead electrode 6 to form a circuit. An aluminum wire, for example, may be used in place of the metal lead electrode 6.

There is no limitation on a type of the semiconductor element 5. In the semiconductor device for controlling electrical power, an IGBT, a diode, and a reverse conducting IGBT of a silicon (Si) material is often used as the semiconductor element 5. A MOSFET or a Schottky diode, for example, formed by a semiconductor material having a larger bandgap than Si such as a semiconductor of silicon carbide (SiC) series or a gallium nitride (GaN) series, for example, can also be used as the semiconductor element 5 of the semiconductor device for controlling electrical power. There is no limitation also on the number of semiconductor elements 5 mounted to the insulating substrate 2, but a necessary number of semiconductor elements 5 are mounted as usage.

The resin case 3 is made up of an external electrode 3a and a resin part 3b. The external electrode 3a is insert molded in the resin part 3b, or may also be inserted and disposed after the resin part 3b is formed. The material of the resin part 3b is generally heat-resistant resin such as PPS (polyphenylene sulfide) or PBT (polybutylene terephthalate), but it is not limited thereto, and it is sufficient that any resin having desired characteristics is selected.

Although the illustration is omitted, a sealing resin having high insulation properties, for example, fills the resin case 3, and the semiconductor element 5, the insulating substrate 2, and the metal lead electrode 6, for example, are thereby sealed. Although silicone gel or epoxy resin is general as the sealing resin, a material of the sealing resin is not limited thereto. It is sufficient that resin having physical properties such as desired modulus of elasticity, heat resistance, adhesion, and a linear expansion coefficient is selected.

The semiconductor device according to the embodiment 1 includes fastening holes 4 in four corners. The fastening hole 4 passes through the metal base plate 1 and the resin case 3. That is to say, the fastening hole 4 is made up of a fastening hole 4a as a first fastening hole formed in the metal base plate 1 and a fastening hole 4b as a second fastening hole formed in the resin case 3. The fastening hole 4a of the metal base plate 1 and the fastening hole 4b of the resin case 3 are disposed to be overlapped with each other.

In the embodiment 1, a protrusion 1a restricting pivot of the resin case 3 is provided to an upper surface of the metal base plate 1 to prevent positional displacement between the fastening hole 4a of the metal base plate 1 and the fastening hole 4b of the resin case 3. As illustrated in FIG. 2, the protrusion 1a is provided in a region between the fastening holes 4a adjacent to each other of the metal base plate 1. The protrusion 1a is provided in one or more positions in the metal base plate 1, and any position, shape, and length (height) thereof is applicable as long as it can restrict pivot of the resin case 3. Any position in the region between the fastening holes 4a adjacent to each other of the metal base plate 1 is applicable as the position of the protrusion 1a. Described herein is an example that the shape of the protrusion 1a is a quadrangular prism; however, the shape thereof may be a circular column or a quadrangular pyramid or a circular cone with a narrowing distal end (tapered shape), for example.

A groove 3c corresponding to the protrusion 1a of the metal base plate 1 is provided to a lower surface (that is to say, a surface having direct contact with the metal base plate 1) of the resin case 3. The resin case 3 is positioned so that the protrusion 1a is fitted to the groove 3c and is disposed on the metal base plate 1 as illustrated in FIG. 3.

Described hereinafter is an example of a process of assembling the semiconductor device according to the embodiment 1. The assembly process includes a first process to a fifth process described hereinafter.

### [First Process]

In a first process, the metal base plate 1, the insulating substrate 2, and the semiconductor element 5 are bonded using a bonding material such as a plate solder, a solder paste, or the other a soft solder. A solder is generally used as the bonding material in many cases. The bonding process is performed at a temperature higher than a melting point of the bonding material used in the bonding process. The bonding material may be previously molded as with a plate solder, or may also be applied by screen printing or a dispensing a solder paste.

### [Second Process]

In a second process, an adhesive agent of silicone series or epoxy series is applied to an outer surrounding part of the metal base plate 1 bonded to the resin case 3, and the metal base plate 1 is disposed on a jig. Subsequently, the resin case 3 is disposed on the metal base plate 1, and the metal base plate 1 and the resin case 3 are fastened by a screw together with the jig, thus have pressure-contact with each other. In this state, the metal base plate 1 and the resin case 3 are heated to cure the adhesive agent.

### [Third Process]

In a third process, the metal lead electrode 6 is solder-bonded to the semiconductor element 5 to form a circuit. The screw attached in the second process is detached after the third process.

### [Fourth Process]

In a fourth process, a control electrode (not shown) of the semiconductor element 5 and an external signal terminal (not shown) for inputting a control signal are connected by ultrasonic-bonding a wire, for example, Aluminum having high heat conductivity or electrical conductivity is used as a material of the wire in many cases.

### [Fifth Process]

In a fifth process, a sealing resin fills the resin case 3 to seal the semiconductor element 5, the insulating substrate 2, and the metal lead electrode 6, for example. Although a silicone gel or an epoxy resin is used as the sealing resin in many cases, a material of the sealing resin is not limited thereto. It is sufficient that a material having physical properties such as desired modulus of elasticity, heat resistance, adhesion, and a linear expansion coefficient is selected. Subsequently, a semi-manufactured product is put in a curing furnace to cure the sealing resin.

The configuration of the semiconductor device is completed by the processes described above. Subsequently, a product of the semiconductor device is completed through necessary electrical characteristics.

According to the semiconductor device in the embodiment 1, the metal base plate 1 includes the protrusion 1a, and the groove 3c to which the protrusion 1a is fitted is provided to the resin case 3. Thus, pivot of the resin case 3 by a torque of screwing is restricted in fastening the metal base plate 1 and the resin case 3 by the screw in the second process. Thus, prevented is positional displacement between the fastening hole 4a of the metal base plate 1 and the fastening hole 4b of the resin case 3.

### Embodiment 2

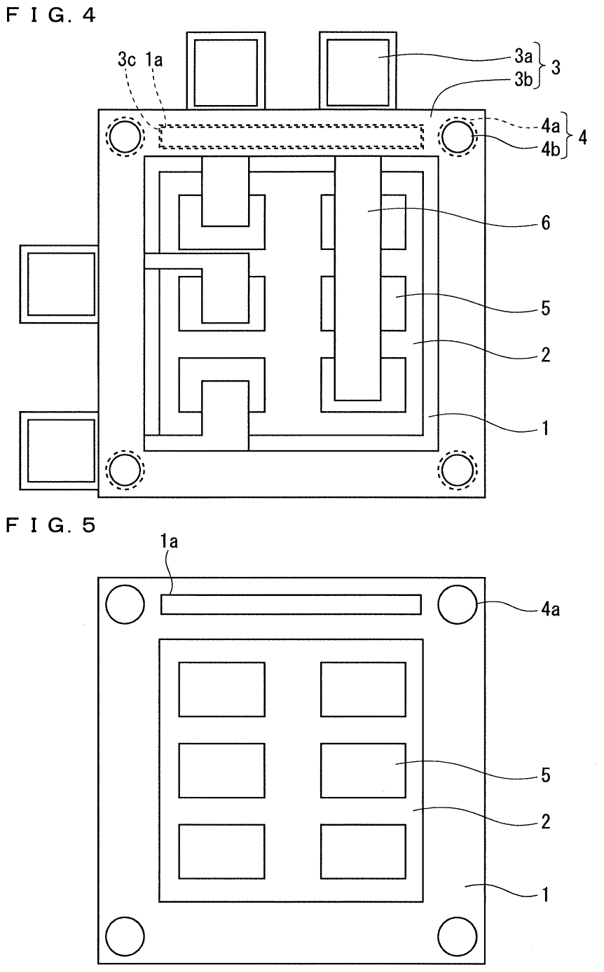

FIG. 4 and FIG. 5 are plan views each illustrating a configuration of a semiconductor device according to an embodiment 2. FIG. 4 is a plan view of the semiconductor device, and FIG. 5 is a plan view that a resin case of the semiconductor device is omitted from FIG. 4.

In the semiconductor device according to the embodiment 2, a shape of the protrusion 1a provided to the metal base plate 1 has a linear shape (that is to say, an elongated rectangular shape) in a plan view. That is to say, the metal base plate 1 includes the protrusion 1a with a linear shape extending between the fastening holes 4a adjacent to each other. A groove 3c with a linear shape to which the linear protrusion 1a is fitted is provided in a position corresponding to the protrusion 1a of the metal base plate 1 in the resin case 3. The protrusion 1a is provided in one or more positions in the metal base plate 1.

According to the semiconductor device in the embodiment 2, the protrusion 1a of the metal base plate 1 restricts pivot of the resin case 3 due to a torque in fastening a screw in the second process in the manner similar to the embodiment 1. Particularly, since the protrusion 1a has the linear shape, an amount of displacement of the metal base plate 1 in a rotational direction is suppressed more than the embodiment 1, and positional displacement between the fastening hole 4a of the metal base plate 1 and the fastening hole 4b of the resin case 3 further hardly occurs.

### Embodiment 3

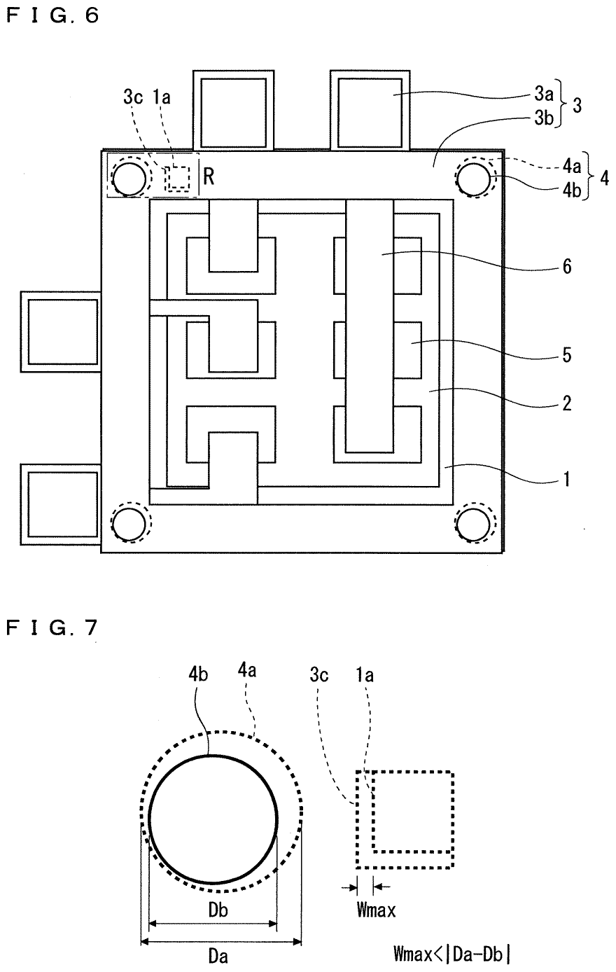

FIG. 6 and FIG. 7 are plan views each illustrating a configuration of a semiconductor device according to an embodiment 3. FIG. 6 is a plan view of the semiconductor device, and FIG. 7 is an enlarged view of a region R in FIG. 6.

A basic configuration of the semiconductor device according to the embodiment 3 is similar to that in the embodiment 1 or 2. FIG. 6 illustrates a state where the position of the resin case 3 is displaced with respect to the metal base plate 1, but the groove 3c of the resin case 3 is caught on the protrusion 1a of the metal base plate 1, and the displacement of the resin case 3 is stopped.

FIG. 7 illustrates a positional relationship between the protrusion 1a of the metal base plate 1 and the groove 3c of the resin case 3 and a positional relationship between the fastening hole 4a of the metal base plate 1 and the fastening hole 4b of the resin case 3 in the state in FIG. 6. As illustrated in FIG. 7, a maximum width Wmax of a gap which can be formed between the protrusion 1a fitted to the groove 3c and an inner wall of the groove 3c is smaller than a difference between a diameter Da of the fastening hole 4a of the metal base plate 1 and a diameter Db of the fastening hole 4b of the resin case 3. That is to say, a relationship of Wmax<|Da−Db| is established.

According to the semiconductor device in the embodiment 3, the relationship of Wmax<|Da−Db| is established. Thus, even when the resin case 3 is pivoted due to the torque in fastening the screw in the second process, the inner wall of the groove 3c of the resin case 3 is caught on the protrusion 1a of the metal base plate 1 before the fastening hole 4b of the resin case 3 is deviated from the fastening hole 4a of the metal base plate 1. Thus, the positional displacement between the fastening hole 4a of the metal base plate 1 and the fastening hole 4b of the resin case 3 does not substantially occur.

### Embodiment 4

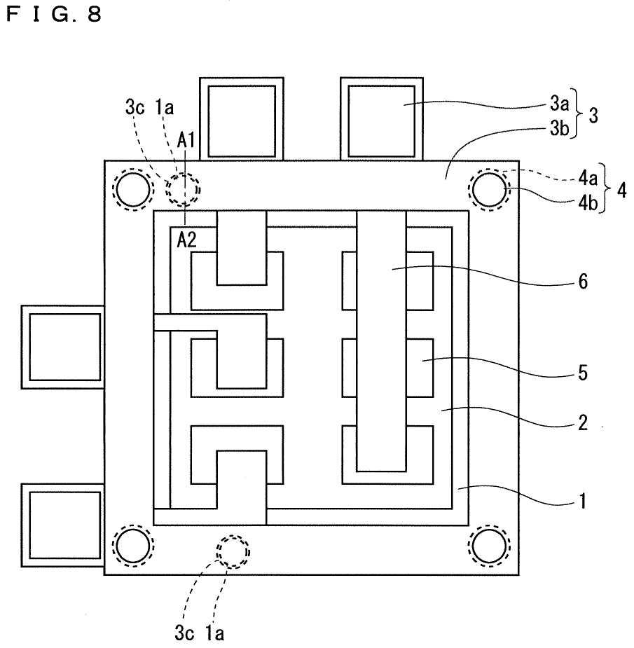

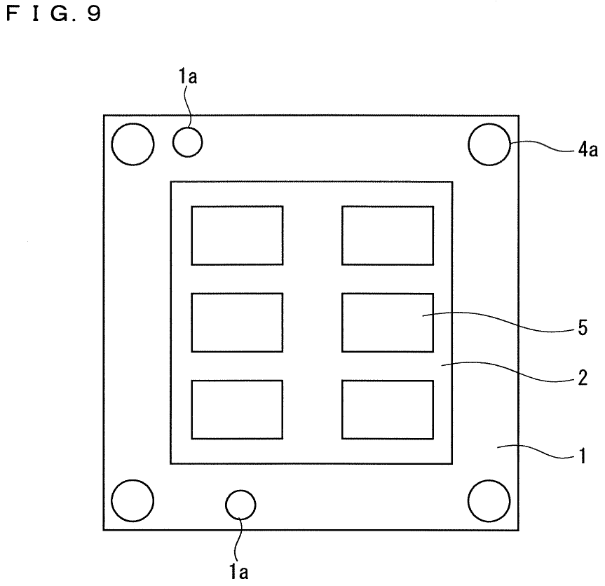

FIG. 8 and FIG. 9 are plan views each illustrating a configuration of a semiconductor device according to an embodiment 4. FIG. 8 is a plan view of the semiconductor device, and FIG. 9 is a plan view that a resin case of the semiconductor device is omitted from FIG. 8.

A plurality of (herein, two) protrusions 1a with a columnar shape are provided to the metal base plate 1 in the semiconductor device according to the embodiment 4. The resin case 3 includes a plurality of circular grooves 3c to which the plurality of columnar protrusions 1a are fitted. Any position in the region between the fastening holes 4a adjacent to each other of the metal base plate 1 is applicable as the position of the columnar protrusion 1a.

Pivot of the resin case 3 due to the screw fastening torque in the second process occurs with a first fastening position as a center. In the embodiment 3 described above, the maximum width (Wmax) of the gap between the protrusion 1a and the inner wall of the groove 3c needs to be designed so that positional displacement between the fastening hole 4a of the metal base plate 1 and the fastening hole 4b of the resin case 3 does not occur even in a position away from the first fastening position. In contrast, in the embodiment 4, two or more columnar protrusions 1a are provided. Thus, the amount of displacement of the metal base plate 1 in the rotational direction is suppressed, and the maximum width of the gap between the protrusion 1a and the inner wall of the groove 3c is easily designed.

### Embodiment 5

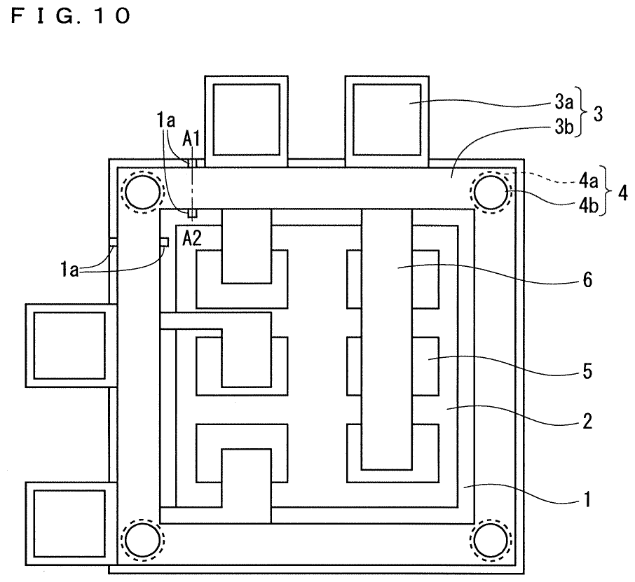

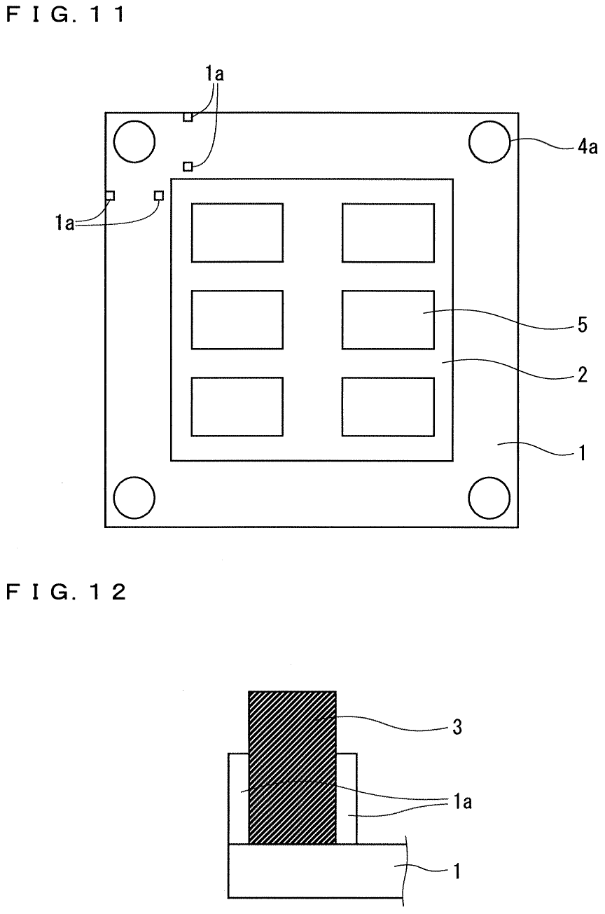

FIG. 10, FIG. 11, and FIG. 12 are diagrams each illustrating a configuration of a semiconductor device according to an embodiment 5. FIG. 10 is a plan view of the semiconductor device, FIG. 11 is a plan view that a resin case of the semiconductor device is omitted from FIG. 10, and FIG. 12 is cross-sectional view along an A1-A2 line in FIG. 10.

In the semiconductor device according to the embodiment 5, one or more pairs of protrusions 1a disposed to sandwich a part of the resin case 3 are provided to each of two sides which are not parallel to each other of the metal base plate 1. There is no limitation on a shape and a height of two protrusions 1a as the pair. Since the pair of protrusions 1a sandwiches a part of the resin case 3, thereby restricting pivot of the resin case 3, the groove 3c needs not be formed in the resin case 3.

According to the semiconductor device in the embodiment 5, the protrusion 1a of the metal base plate 1 restricts pivot of the resin case 3 due to a torque in fastening a screw in the second process in the manner similar to the embodiment 1. Particularly, since the pair of protrusions 1a are formed to sandwich a part of the metal base plate 1, the groove 3c needs not be formed in the resin case 3.

### Embodiment 6

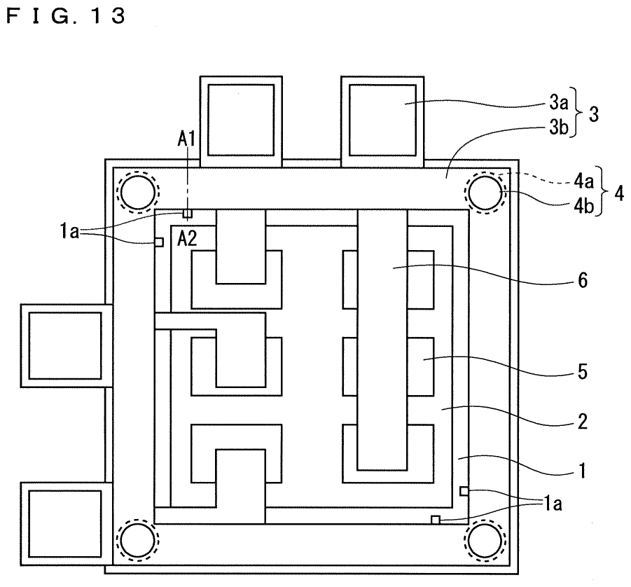

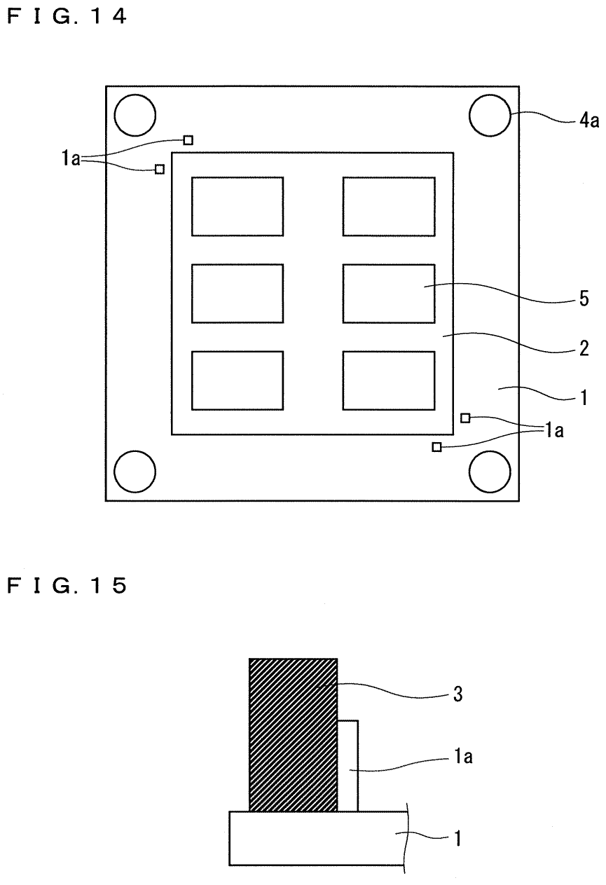

FIG. 13, FIG. 14, and FIG. 15 are diagrams each illustrating a configuration of a semiconductor device according to an embodiment 6. FIG. 13 is a plan view of the semiconductor device, FIG. 14 is a plan view that a resin case of the semiconductor device is omitted from FIG. 13, and FIG. 15 is cross-sectional view along an A1-A2 line in FIG. 13.

In the semiconductor device according to the embodiment 6, one or more protrusions 1a disposed inside the resin case 3 are provided to each side of the metal base plate 1. Thus, four or more protrusions 1a are provided inside the resin case 3 in the metal base plate 1. The plurality of protrusions 1a are fitted inside the resin case 3 when the resin case 3 is disposed on the metal base plate 1.

According to the semiconductor device in the embodiment 6, the protrusion 1a of the metal base plate 1 restricts pivot of the resin case 3 due to a torque in fastening a screw in the second process in the manner similar to the embodiment 1. Particularly, when the protrusion 1a is provided to each side of the metal base plate 1, displacement of the metal base plate 1 in a horizontal direction is also suppressed. Thus, positional displacement between the fastening hole 4a of the metal base plate 1 and the fastening hole 4b of the resin case 3 further hardly occurs. Since the inner wall of the resin case 3 is locked to the protrusion 1a, the groove 3c needs not be formed in the resin case 3. Such a configuration is effective in a case where it is difficult to locate some of the protrusions 1a outside the resin case 3 as with the embodiment 5.

### Embodiment 7

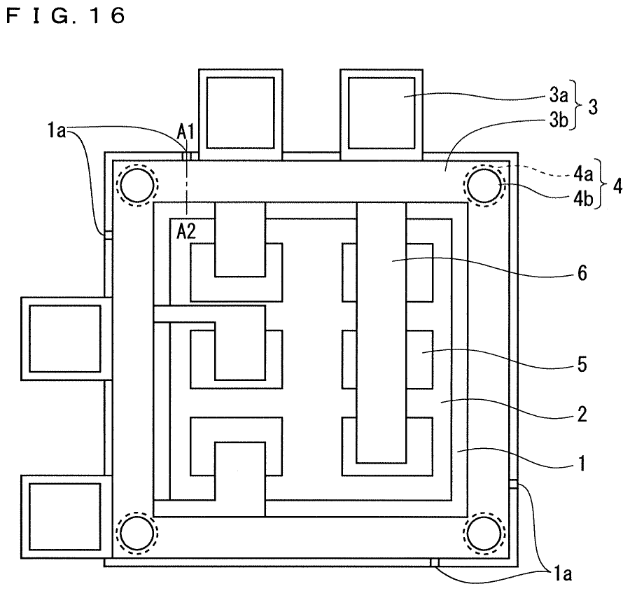

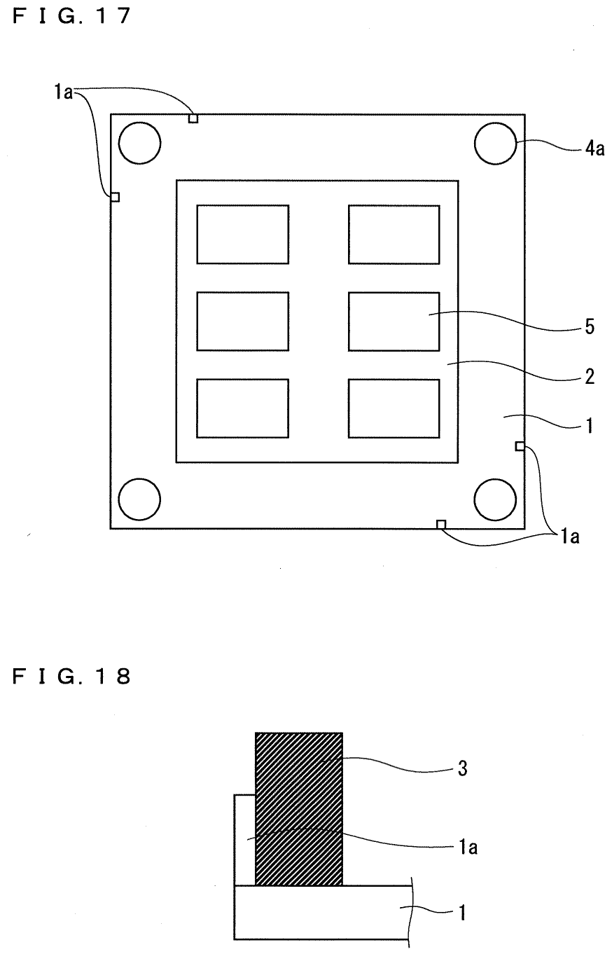

FIG. 16, FIG. 17, and FIG. 18 are diagrams each illustrating a configuration of a semiconductor device according to an embodiment 7. FIG. 16 is a plan view of the semiconductor device, FIG. 17 is a plan view that a resin case of the semiconductor device is omitted from FIG. 16, and FIG. 18 is cross-sectional view along an A1-A2 line in FIG. 16.

In the semiconductor device according to the embodiment 7, one or more protrusions 1a disposed outside the resin case 3 are provided to each side of the metal base plate 1. Thus, four or more protrusions 1a are provided outside the resin case 3 in the metal base plate 1. The protrusion 1a on each side is located outside the resin case 3 when the resin case 3 is disposed on the metal base plate 1.

According to the semiconductor device in the embodiment 7, the protrusion 1a of the metal base plate 1 restricts pivot of the resin case 3 due to a torque in fastening a screw in the second process in the manner similar to the embodiment 1. Particularly, when the protrusion 1a is provided to each side of the metal base plate 1 in the manner similar to the embodiment 6, displacement of the metal base plate 1 in a horizontal direction is also suppressed. Thus, positional displacement between the fastening hole 4a of the metal base plate 1 and the fastening hole 4b of the resin case 3 further hardly occurs. Since the outer wall of the resin case 3 is locked to the protrusion 1a, the groove 3c needs not be formed in the resin case 3. Such a configuration is effective in a case where it is difficult to locate all of the protrusions 1a inside the resin case 3 as with the embodiment 6.

### Embodiment 8

A basic configuration of a semiconductor device according to the embodiment 8 is similar to that of the embodiment 5, 6, or 7. A maximum width of a gap which can be formed between the resin case 3 mounted to the metal base plate 1 and the protrusion 1a of the metal base plate 1 is further designed to be smaller than a difference between the fastening hole 4b of the resin case 3 and the diameter of the fastening hole 4a. That is to say, when the maximum width of the gap between the resin case 3 and the protrusion 1a of the metal base plate 1 is Wmax, the diameter of the fastening hole 4b of the resin case 3 is Da, and the diameter of the fastening hole 4a is Db, a relationship of Wmax<|Da−Db| is established.

According to the semiconductor device in the embodiment 8, the relationship of Wmax<|Da−Db| is established. Thus, even when the resin case 3 is pivoted due to the torque in fastening the screw in the second process, the resin case 3 is caught on the protrusion 1a of the metal base plate 1 before the fastening hole 4b of the resin case 3 is deviated from the fastening hole 4a of the metal base plate 1. Thus, the positional displacement between the fastening hole 4a of the metal base plate 1 and the fastening hole 4b of the resin case 3 does not substantially occur.

Each embodiment can be arbitrarily combined, or each embodiment can be appropriately varied or omitted.

The foregoing description is in all aspects illustrative, and it is therefore understood that numerous modifications not exemplified can be devised.

### EXPLANATION OF REFERENCE SIGNS

1 metal base plate, 1a protrusion, 2 insulating substrate, 3 resin case, 3a external electrode, 3b resin part, 3c groove, 4 fastening hole, 4a fastening hole of metal base plate, 4b fastening hole of resin case, 5 semiconductor element, 6 metal lead electrode.

1. A semiconductor device, comprising:
a semiconductor element;
an insulating substrate to which the semiconductor element is mounted;
a metal base plate to which the insulating substrate is mounted;
a resin case provided on the metal base plate to surround the insulating substrate;
a plurality of first fastening holes formed in the metal base plate;
a plurality of second fastening holes formed in the resin case and disposed to be overlapped with the plurality of first fastening holes; and
at least one protrusion provided in a region between the first fastening holes adjacent to each other in the metal base plate to restrict pivot of the resin case.

2. The semiconductor device according to claim 1, wherein
the resin case includes at least one groove to which the protrusion is fitted.

3. The semiconductor device according to claim 2, wherein
the metal base plate includes the protrusion with a linear shape extending between the first fastening holes adjacent to each other, and
the resin case includes the groove with a linear shape to which the protrusion with the linear shape is fitted.

4. The semiconductor device according to claim 2, wherein
the metal base plate includes the plurality of protrusions with a columnar shape, and
the resin case includes the plurality of grooves with a circular shape to which the plurality of protrusions with the columnar shape are fitted.

5. The semiconductor device according to claim 2, wherein
a maximum width of a gap which can be formed between the protrusion fitted to the groove and an inner wall of the groove is smaller than a difference between a diameter of each of the first fastening holes and a diameter of each of the second fastening holes.

6. The semiconductor device according to claim 1, wherein
the metal base plate includes a pair of protrusions disposed to sandwich a part of the resin case in each of two sides which are not parallel to each other of the metal base plate.

7. The semiconductor device according to claim 1, wherein
the metal base plate includes the protrusion disposed inside the resin case on each side of the metal base plate.

8. The semiconductor device according to claim 1, wherein
the metal base plate includes the protrusion disposed outside the resin case on each side of the metal base plate.

9. The semiconductor device according to claim 6, wherein
a maximum width of a gap which can be formed between the resin case mounted to the metal base plate and the protrusion is smaller than a difference between a diameter of each of the second fastening holes and a diameter of each of the first fastening holes.

10. The semiconductor device according to claim 3, wherein
a maximum width of a gap which can be formed between the protrusion fitted to the groove and an inner wall of the groove is smaller than a difference between a diameter of each of the first fastening holes and a diameter of each of the second fastening holes.

11. The semiconductor device according to claim 4, wherein
a maximum width of a gap which can be formed between the protrusion fitted to the groove and an inner wall of the groove is smaller than a difference between a diameter of each of the first fastening holes and a diameter of each of the second fastening holes.

12. The semiconductor device according to claim 7, wherein
a maximum width of a gap which can be formed between the resin case mounted to the metal base plate and the protrusion is smaller than a difference between a diameter of each of the second fastening holes and a diameter of each of the first fastening holes.

13. The semiconductor device according to claim 8, wherein
a maximum width of a gap which can be formed between the resin case mounted to the metal base plate and the protrusion is smaller than a difference between a diameter of each of the second fastening holes and a diameter of each of the first fastening holes.
